(19) United States
(12) Patent Application Publication
(10) Pub. No.: US 2015/0108516 A1
(43) Pub. Date: Apr. 23, 2015

(54) LIGHT EMITTING DIODE PACKAGE STRUCTURE AND LIGHT EMITTING DIODE PACKAGE MODULE

(71) Applicant: Lextar Electronics Corporation, Hsinchu (TW)

(72) Inventor: Li-Cheng YANG, Zhongli City (TW)

(73) Assignee: Lextar Electronics Corporation, Hsinchu (TW)

(21) Appl. No.: 14/278,564

(22) Filed: May 15, 2014

(30) Foreign Application Priority Data
Oct. 22, 2013 (TW) 102138104

(51) Int. Cl. H01L 33/50; H01L 33/54; H01L 27/15

(52) U.S. Cl. CPC H01L 33/507; H01L 27/156; H01L 33/54
USPC 257/89; 257/98

(57) ABSTRACT

A light emitting diode package structure includes a substrate, a light emitting diode chip, a light mixing encapsulating layer, and an ultraviolet protecting layer. The light emitting diode chip is disposed on a surface of the substrate and the light mixing encapsulating layer covers the light emitting diode chip. The ultraviolet protecting layer is adhered to a surface of the light mixing encapsulating layer such that when the ultraviolet protecting layer receives ultraviolet, the color change occurs to reflect or absorb the ultraviolet.

### RELATED APPLICATIONS

This application claims priority to Taiwan Application Serial Number 102138104, filed Oct. 22, 2013, which is herein incorporated by reference.

### BACKGROUND

1. Field of Invention

The present invention relates to a type of light emitting diode package structure and light emitting diode package module.

2. Description of Related Art

In recent years, with the successful mass production of blue light diodes, the range of application of Light Emitting Diodes (LEDs) increases significantly; moreover, with the improved LED production yield, the unit manufacturing cost is lowered, and the demand for the LEDs continues to increase in the industry. In terms of the characteristics, the LEDs have a small size, long lifespan, small power consumption and so on. In this regard, the LEDs have been widely adopted as indicators in 3C (computer, communication, consumer) electronics and display devices.

However, the LEDs that are generally used in outdoor lightings easily result in reduced lifespan since the LEDs are exposed to sunlight. For example, when the ultraviolet light of the sun irradiates on the LEDs, the LEDs are vulnerable to damage from overheating, and the LEDs is apt to be deteriorated under long term ultraviolet light exposure.

### SUMMARY

One aspect of the invention is to provide a light emitting diode package structure and a light emitting diode package module to solve the problems of the conventional technology.

According to one embodiment of the present invention, providing a light emitting diode package structure, which includes a substrate, a light emitting diode chip configured to emit a light of first wavelength, a light mixing encapsulating layer and an ultraviolet protecting layer. The light emitting diode chip is disposed on the surface of the substrate, the light mixing encapsulating layer covers the light emitting diode chip, the light mixing encapsulating layer has a wavelength conversion material to convert part of the light of first wavelength to a light of second wavelength, and mix with the light of first wavelength that is not converted to the second wavelength to form a white light. The ultraviolet protecting layer adhere to a surface of the light mixing encapsulating layer, when the ultraviolet protecting layer receives a light of ultraviolet band, color change occurs to reflect or absorb light of the ultraviolet band.

According to one embodiment of the present invention, the ultraviolet protecting layer is a photochromic layer.

According to one embodiment of the present invention, the material of the photochromic layer is silver halide (AgX) or spiropyran.

According to one embodiment of the present invention, the thickness of the ultraviolet protecting layer is between 1 μm to 40 μm.

According to one embodiment of the present invention, the thickness of the ultraviolet protecting layer is between 5 μm to 10 μm.

According to one embodiment of the present invention, the light emitting diode package structure further includes a cup portion, located on the surface of the substrate and disposed around the light emitting diode chip. This cup portion and the substrate forms a notch that contains the light emitting diode chip, the light mixing encapsulating layer is filled in the notch.

According to one embodiment of the present invention, the light emitting diode package structure further includes a die attachment adhesive, binding the light emitting diode chip and the substrate.

According to another embodiment of the present invention, the light emitting diode package module includes a substrate, a plurality of light emitting diode chips configured to emit a light of first wavelength, a plurality of light mixing encapsulating layers, a transparent housing, and an ultraviolet protecting layer. The plurality of light emitting diode chips is disposed on the surface of the substrate. A plurality of light mixing encapsulating layers respectively covers the light emitting diode chips, each light mixing encapsulating layer has a wavelength conversion material to convert part of the light of first wavelength to a light of second wavelength, and mix with the light of first wavelength that is not converted to the second wavelength to form a white light. The transparent housing covers the light emitting diode chips and the light mixing encapsulating layers, the ultraviolet protecting layer adheres to a surface of the transparent housing, when the ultraviolet protecting layer receives a light of ultraviolet band, color change occurs to reflect or absorb light of the ultraviolet band.

According to one embodiment of the present invention, the ultraviolet protecting layer is a photochromic layer.

According to one embodiment of the present invention, when the ultraviolet protecting layer occurs color change, the ultraviolet protecting layer has a predetermined pattern to modulate the plurality of spatial distributions emitted by the light emitting diode chip.

According to one embodiment of the present invention, the material of the photochromic layer is silver halide (AgX) or spiropyran.

In summary, the present invention, via covering the light mixing encapsulating layer or the transparent housing with the ultraviolet protecting layer, can protect the internal light emitting diode chip, via the occurrence of color change of the ultraviolet protecting layer, when the light emitting diode package structure and the light emitting diode package module absorbs ultraviolet light irradiation.

### BRIEF DESCRIPTION OF THE DRAWINGS

The invention can be more fully understood by reading the following detailed description of the embodiment, with reference made to the accompanying drawings as follows:

FIG. 1 illustrates the first embodiment of the light emitting diode package structure of the invention.

FIG. 2A illustrates the schematic diagram of the spatial distribution when the light emitting diode package structure of FIG. 1 has not absorbed ultraviolet light irradiation yet.

FIG. 2B to FIG. 2C illustrates the change in spatial distribution when the duration that the light emitting diode package structure of FIG. 1 absorbs ultraviolet light irradiation changes.

FIG. 3 illustrates the relationship between the wavelength of the light versus the light transmittance rate of the ultraviolet protecting layer of FIG. 2A to FIG. 2C.

FIG. 4 illustrates the second embodiment of the light emitting diode package structure of the invention.

FIG. 5 illustrates the first embodiment of the light emitting diode package module of the invention.

FIG. 6 illustrates the second embodiment of the light emitting diode package module of the invention.

### DETAILED DESCRIPTION

The invention can be more fully understood by reading the following detailed description of the embodiment, with reference made to the accompanying drawings. Wherever possible, the same reference numbers are used in the drawings and the description to refer to the same or like parts. However, the embodiments are not provided to limit the scope covered in the invention, and the description of the operation of the structures is not intended to limit the order in which to perform, any structure formed by re-combination of the elements that result in a device with equal effect are all covered in the scope of the invention.

The drawings are for illustration purposes only, and are not drawn in accordance with the original size. On the other hand, well-known elements and steps are not described in the embodiments to avoid unnecessary limitations to the invention.

The following embodiments disclose a light emitting diode package structure and a light emitting diode package module, all of which contains an ultraviolet protecting layer that partially or fully covers the light emitting diode in the light emitting diode package structure and the light emitting diode package module to prevent the light emitting diode from receiving the ultraviolet light in the sunlight that causes reduced lifespan.

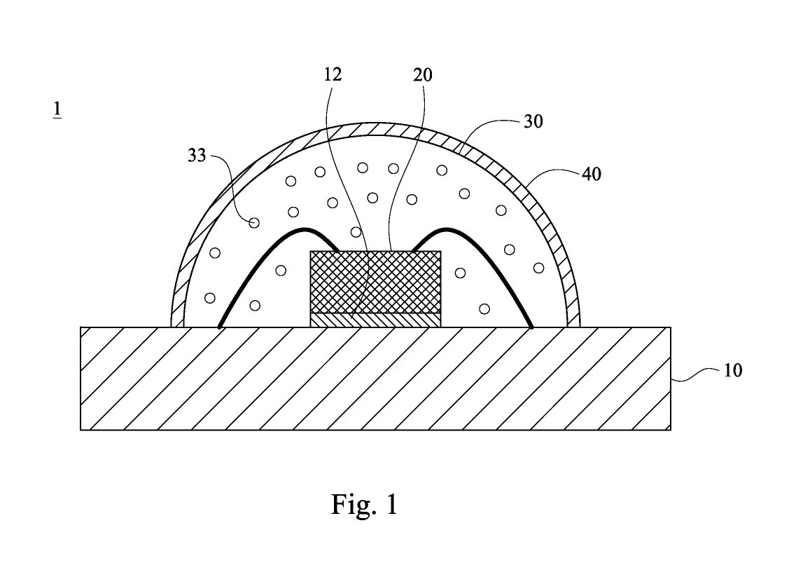

Please refer to FIG. 1, which illustrates the first embodiment of the light emitting diode package structure of the invention. As shown in the figure, a light emitting diode package structure 1 includes a substrate 10, a light emitting diode chip 20, a light mixing encapsulating layer 30 and an ultraviolet protecting layer 40.

A die attachment adhesive 12 is disposed on the surface of the substrate 10 of the light emitting diode package structure 1, binding the light emitting diode chip 20 and the substrate 10, used to fixedly dispose the light emitting diode chip 20 on the surface of the substrate 10. The light emitting diode chip 20 is configured to emit a light of first wavelength. In this embodiment, the first wavelength can be, but not limited to, blue light of 450 nanometers to 500 nanometers. In other embodiments of the invention, the first wavelength can be the wavelength range of red light or the wavelength range of green light.

The light mixing encapsulating layer 30 covers the light emitting diode chip 20, and the light mixing encapsulating layer 30 contains a wavelength conversion material 33 within. The wavelength conversion material 33 can convert the light of first wavelength to a light of second wavelength, and mix with the light of first wavelength that is not converted to the second wavelength to form a white light. For example, if the light emitting diode chip 20 is a blue light diode, then the wavelength conversion material 33 can be phosphors, when a portion of the blue light emitted by the light emitting diode chip 20 hits the phosphors, it can be converted to yellow light, and mix with the original blue light that have not been converted by the phosphors to form white light.

After the light mixing encapsulating layer 30 covers the light emitting diode chip 20, the ultraviolet protecting layer 40 can adhere to a surface of the light mixing encapsulating layer 30. In this embodiment, the ultraviolet protecting layer 40 can use a, but not be limited, coating manner to adhere to a surface of the light mixing encapsulating layer 30. In other embodiments of the invention, the ultraviolet protecting layer 40 can be formed on the surface of the light mixing encapsulating layer 30 by using a spraying or spin coating manner.

In this embodiment, the ultraviolet protecting layer 40 can be a photochromic layer. More specifically, the ultraviolet protecting layer 40 can be a material that will occur change in color when irradiated with ultraviolet light, for example, materials such as silver halide (AgX) or spiropyran. Therefore, when the ultraviolet protecting layer 40 of this embodiment receives light of ultraviolet band, to protect the light emitting diode chip 20 from damage due to light of ultraviolet band, color change will occur to reflect or absorb ultraviolet light.

It is worth mentioning that, in this embodiment, the thickness of the ultraviolet protecting layer 40 is, but not limited to, between 5 μm and 10 μm. In other embodiments of the invention, the thickness of the ultraviolet protecting layer 40 can be between 1 μm and 40 μm. If the thickness of the ultraviolet protecting layer 40 is greater than 40 μm, the process may then need coating to be done more than twice, which would make it difficult for the ultraviolet protecting layer 40 to adhere to the light mixing encapsulating layer 30, and if the thickness of the ultraviolet protecting layer 40 is less than 1 μm, the ultraviolet protecting layer 40 is then less capable to reflect or absorb the ultraviolet light, and thus not able to protect the light emitting diode chip 20 from the ultraviolet light harm.

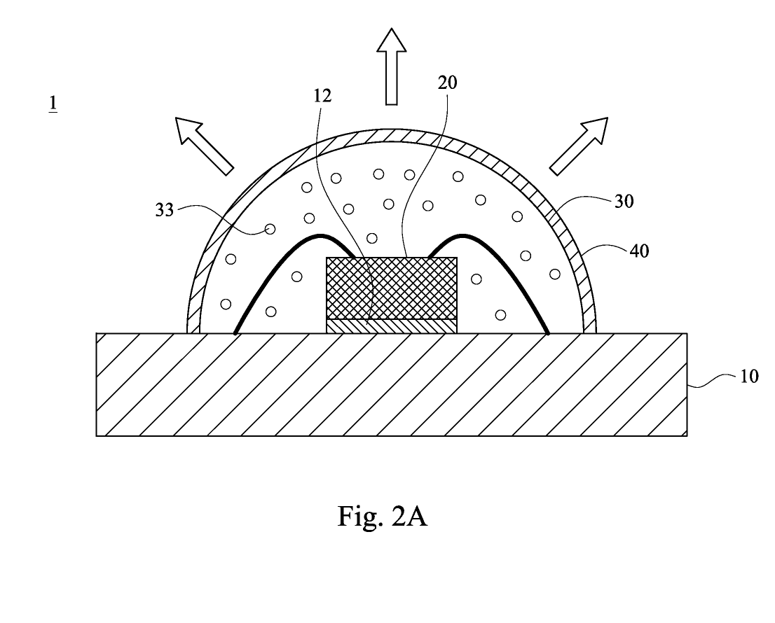

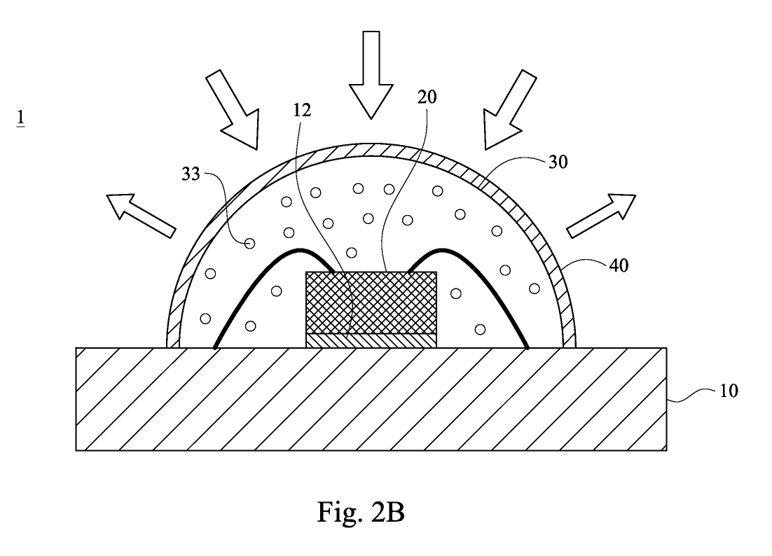

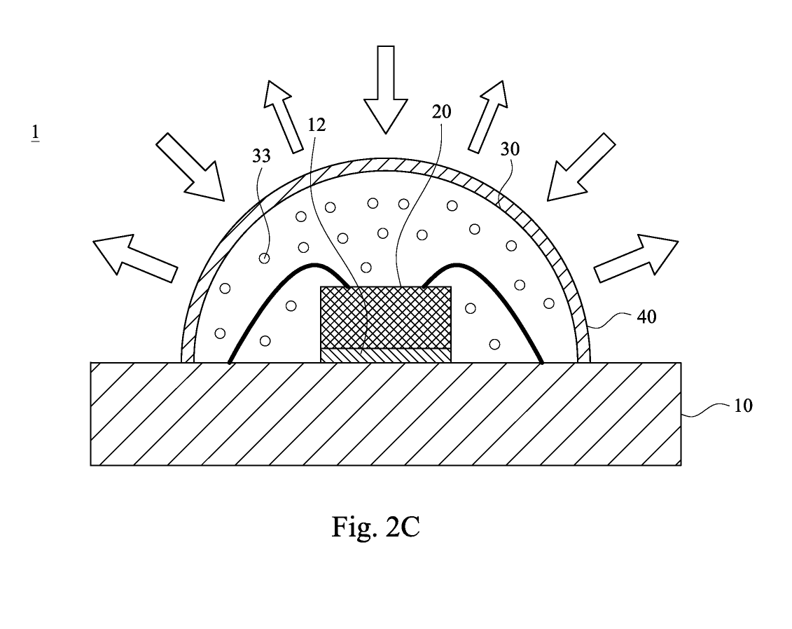

For easier understanding, please also refer to FIG. 2A to FIG. 2C, FIG. 2A illustrates the schematic diagram of the spatial distribution when the light emitting diode package structure of FIG. 1 has not absorbed ultraviolet light irradiation yet. FIG. 2B to FIG. 2C illustrates the change in spatial distribution when the duration that the light emitting diode package structure of FIG. 1 absorbs ultraviolet light irradiation changes.

In FIG. 2A, the light emitting diode package structure of FIG. 1 has not absorbed ultraviolet light irradiation yet, therefore the light emitted by the light emitting diode package structure 1 can directly transmit through the ultraviolet protecting layer 40, this is usually the case in the evening when there is no sunlight.

Next, as shown in FIG. 2B, when outdoors during the day, the light emitting diode package structure 1 starts to absorb ultraviolet light irradiation, at this moment the ultraviolet protecting layer 40 absorbs ultraviolet light, color change will occur to reflect the ultraviolet light. But since the duration of the ultraviolet light irradiation is shorter or the ultraviolet light irradiation is just absorbed in FIG. 2B, less molecules react with the ultraviolet light, resulting in less capability to reflect ultraviolet light.

Next, as shown in FIG. 2C, with longer duration of ultraviolet light irradiation, since more molecules react with the ultraviolet light, the ultraviolet protecting layer 40 can reflect more and more ultraviolet light, at this moment the color change of the ultraviolet protecting layer 40 will be greater compared with the ultraviolet protecting layer 40 of FIG. 2B. That is, the ultraviolet protecting layer 40 of FIG. 2C has a deeper color compared to the ultraviolet protecting layer 40 FIG. 2B. Therefore, the light emitting diode package structure 1 of this embodiment can protect the light emitting diode chip 20 against ultraviolet light harm when used in outdoor illumination, thus increasing the usage lifespan of the outdoor light emitting diode luminaire.

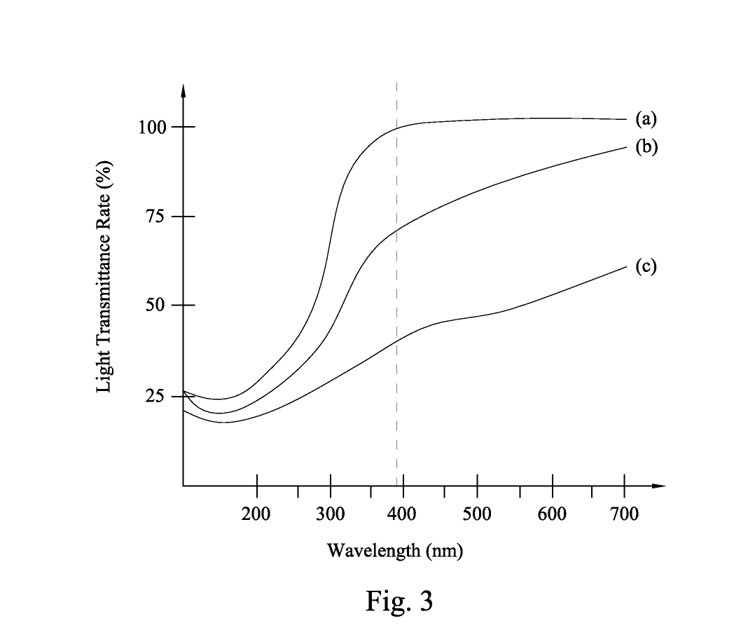

Next please refer to FIG. 3, which illustrates the relationship between the wavelength of the light versus the light transmittance rate of the ultraviolet protecting layer of FIG. 2A to FIG. 2C, wherein the thickness of the ultraviolet protecting layer 40 is 5 μm to 10 μm as an example in FIG. 3, where line (a), line (b) and line (c) in the figure represents the light transmittance rate of FIG. 2A, FIG. 2B, and FIG. 2C. As shown in the figure, since FIG. 2A has not absorbed ultraviolet light irradiation yet, therefore it will not detect that there is ultraviolet light transmittance, therefore the ultraviolet light transmittance rate of line (a) in the ultraviolet band (10 nm to 380 nm) is similar to line (b) and line (c). However, since the ultraviolet protecting layer 40 of FIG. 2A has not absorbed ultraviolet light irradiation yet, therefore no color change has occurred in the ultraviolet protecting layer 40 yet, as a result the visible light (400 nm to 700 nm) of line (a) can transmit through the ultraviolet protecting layer 40 completely.

Next please refer to line (b) and line (c) in FIG. 3, which respectively represents the ultraviolet light transmittance rate of FIG. 2B and FIG. 2C. As shown in the figure, in FIG. 2B, since the duration of the ultraviolet light irradiation absorbed by the ultraviolet protecting layer 40 is shorter compared to FIG. 2C, therefore the ultraviolet light transmittance rate of line (b) is slightly higher than the ultraviolet light transmittance rate of line (c). And in the visible light wavelength portion, since the duration of the ultraviolet light irradiation absorbed by the ultraviolet protecting layer 40 in FIG. 2B is shorter, therefore the color change of the ultraviolet protecting layer 40 is lighter compared to FIG. 2C,thus in the visible light band, the visible light transmittance rate of line (b) will be greater than line (c).

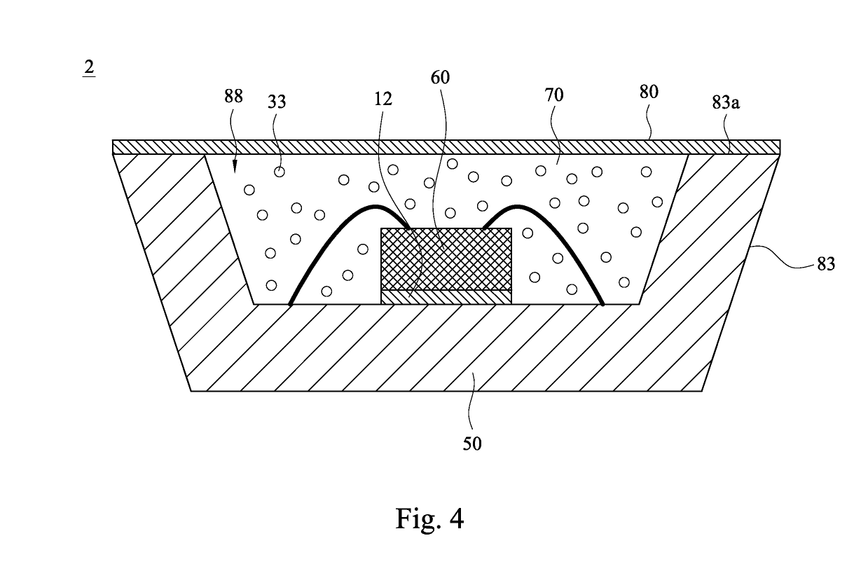

Please refer to FIG. 4, which illustrates the second embodiment of the light emitting diode package structure of the invention. As shown in the figure, the light emitting diode package structure 2 includes a substrate 50, a light emitting diode chip 60, a light mixing encapsulating layer 70, and an ultraviolet protecting layer 80.

A die attachment adhesive 12 is disposed on the substrate 50 of the light emitting diode package structure 2, binding the light emitting diode chip 60 and the substrate 50, to fixedly dispose the light emitting diode chip 60 on the surface of the substrate 50. The biggest difference between this embodiment and the first embodiment lies in that the light emitting diode package structure 2 of the present embodiment further includes a cup portion 83. The cup portion 83 is located on the surface of the substrate 50 and disposed around the light emitting diode chip 60, the cup portion 83 and the substrate 50 can form a notch 88, the light emitting diode chip 60 is disposed within the notch 88, and the light mixing encapsulating layer 70 can be filled within the notch 88. In the actual manufacturing process of the product, the cup portion 83 and the substrate 50 can, but not limited to, be an integrally formed design. In other embodiments of the invention, the materials of the cup portion 83 and the substrate 50 can be different and additionally formed on the surface of the substrate 50.

The light emitting diode chip 60 is configured to emit a light of first wavelength, the light mixing encapsulating layer 70 has a wavelength conversion material 33, used to convert the light of first wavelength to a light of second wavelength, and mix with the light of first wavelength that is not converted to the second wavelength to form a white light.

The ultraviolet protecting layer 80 of the present embodiment covers, but not limited to, the light mixing encapsulating layer 70 and a surface 83a of the cup portion 83. In other embodiment of the invention, the ultraviolet protecting layer 80 can cover only the light mixing encapsulating layer 70, and expose the surface 83a of the cup portion 83.

The ultraviolet protecting layer 80 will react with the ultraviolet light and occur color change and reflect ultraviolet light when receiving irradiation that include light of ultraviolet band. Therefore, the ultraviolet protecting layer 80 of the present embodiment can prevent the light emitting diode chip 60 within the notch 88 from damage due to long term irradiation of ultraviolet light.

The thickness of the ultraviolet protecting layer 80 in the present embodiment is, but not limited to, between 5 μm and 10 μm. In other embodiments of the present invention, the thickness of the ultraviolet protecting layer 80 can range from 1 nm to 40 nm. The material of the ultraviolet protecting layer 80 of the present embodiment can include silver halide (AgX) or spiropyran and other materials.

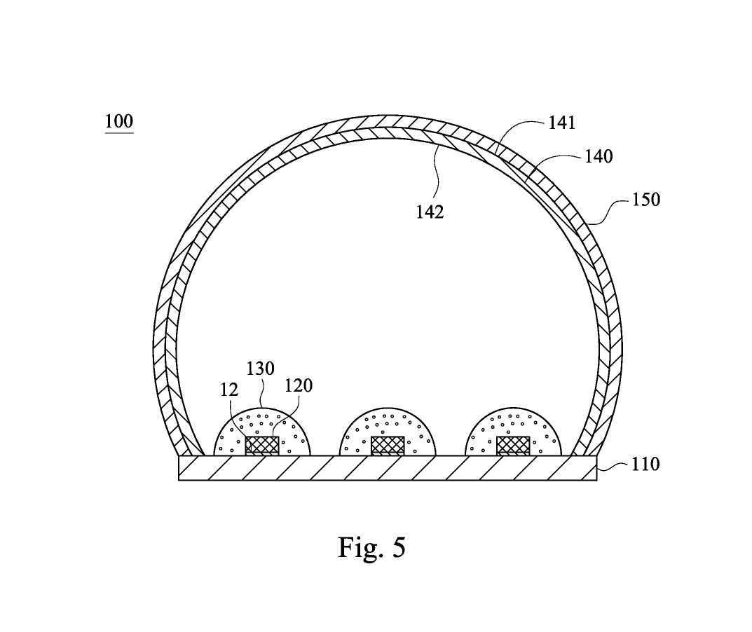

Please refer to FIG. 5, which illustrates the first embodiment of the light emitting diode package module of the invention. As shown in the figure, the light emitting diode package module 100 includes a substrate 110, a plurality of light emitting diode chips 120, a plurality of light mixing encapsulating layers 130, a transparent housing 140 and a ultraviolet protecting layer 150, wherein the plurality of light emitting diode chips 120 can be disposed in array on the surface of the substrate 110, and those said light mixing encapsulating layers 130 respectively cover the light emitting diode chips 120. The light emitting diode chip 120 is configured to emit a light of first wavelength, each light mixing encapsulating layer 130 has a wavelength conversion material 33 to convert part of the light of first wavelength to a light of second wavelength, and mix with the light of first wavelength that is not converted to the second wavelength to form a white light.

The transparent housing 140 covers the light emitting diode chip 120 and the light mixing encapsulating layer 130. The ultraviolet protecting layer 150 adhere to a surface of the transparent housing 140, which can occur color change to reflect or absorb ultraviolet light when the ultraviolet protecting layer 150 absorbs ultraviolet light. In this embodiment, the ultraviolet protecting layer 150 adheres to, but not limited to, the outer surface 141 of the transparent housing 140. In other embodiments, the ultraviolet protecting layer 150 may also adhere to the inner surface 142 of the transparent housing 140.

The ultraviolet protecting layer 150 can be a photochromic layer, for example, materials such as silver halide (AgX) or spiropyran. Therefore, to protect the light emitting diode chip 120 from damage due to ultraviolet light, when the ultraviolet protecting layer 150 of this embodiment absorbs ultraviolet light, color change will occur and reflect or absorb ultraviolet light.

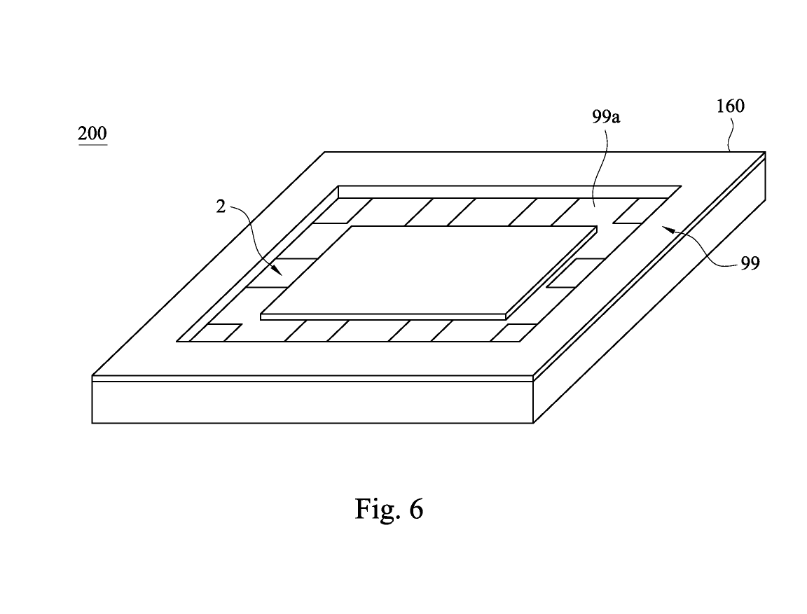

Next please refer to FIG. 6, which illustrates the second embodiment of the light emitting diode package module of the invention. As shown in the figure, the light emitting diode package module 200 of the present embodiment may essentially contain an arrangement of a plurality of light emitting diode package structures 2 of FIG. 4, wherein the ultraviolet protecting layer 160 of the present embodiment can have a predetermined pattern 99, to modulate the emitted spatial distribution of the said light emitting diode package structures 2 when the ultraviolet protecting layer 160 occurs color change.

For example, the predetermined pattern 99 of the present embodiment may be a rectangular frame 99a, the area of the rectangular frame 99a is not coated with the ultraviolet protecting layer 160, while the area inside and the area around the outside of the rectangular frame 99a is still coated with the ultraviolet protecting layer 160. Thus, when the light emitting diode package module 200 of the present embodiment absorbs ultraviolet light, only the portion coated with the ultraviolet protecting layer 160 will have the color change phenomena occur, the rectangular frame 99a portion is still transparent, thus modulating the spatial distribution emitted by the light emitting diode package module 200.

In summary, the embodiments disclosed by the invention provides a light emitting diode package structure and a light emitting diode package module with a ultraviolet protecting layer, when the light emitting diode package structure and the light emitting diode package module absorbs ultraviolet light irradiation, via the reaction of the ultraviolet protecting layer and the ultraviolet light, the color change phenomena will occur to reflect or absorb the ultraviolet light, thus avoiding direct irradiation of the ultraviolet light on the light emitting diode, therefore may protect the light emitting diode chip against damage due to ultraviolet light. In addition, the ultraviolet protecting layer of the light emitting diode package module can have a predetermined pattern so that when the ultraviolet protecting layer absorbs ultraviolet light and occurs color change, the spatial distribution of the light emitting diode package module will also change.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of the invention provided they fall within the scope of the following claims.

What is claimed is:

1. A light emitting diode package structure, comprising:
a substrate;
a light emitting diode chip emitting a light of first wavelength and disposed on a surface of the substrate;
a light mixing encapsulating layer covering the light emitting diode chip, the light mixing encapsulating layer having a wavelength conversion material to convert part of the light of first wavelength to a light of second wavelength, and mix with the light of first wavelength that is not converted to the second wavelength to form a white light; and
an ultraviolet protecting layer adhered to a surface of the light mixing encapsulating layer; when the ultraviolet protecting layer receives a light of ultraviolet band, color change occurs in the ultraviolet protecting layer to reflect or absorb the light of the ultraviolet band.

2. The light emitting diode package structure of claim 1, wherein the ultraviolet protecting layer is a photochromic layer.

3. The light emitting diode package structure of claim 2, wherein the material of the photochromic layer is silver halide (AgX) or spiropyran.

4. The light emitting diode package structure of claim 2, wherein the thickness of the ultraviolet protecting layer is between 1 μm and 40 μm.

5. The light emitting diode package structure of claim 3, wherein the thickness of the ultraviolet protecting layer is between 5 μm and 10 μm.

6. The light emitting diode package structure of claim 1, further comprising a cup portion, located on the surface of the substrate and disposed around the light emitting diode chip, wherein the cup portion and the substrate form a notch that contains the light emitting diode chip, and the light mixing encapsulating layer is filled within the notch.

7. The light emitting diode package structure of claim 1, further comprising a die attachment adhesive binding the light emitting diode chip and the substrate.

8. A light emitting diode package module, comprising:
a substrate;
a plurality of light emitting diode chips emitting a light of first wavelength and disposed in array on a surface of the substrate;
a plurality of light mixing encapsulating layers respectively covering the light emitting diode chips, each of the light mixing encapsulating layer having a wavelength conversion material to convert part of the light of first wavelength to a light of second wavelength and mix with the light of first wavelength that is not converted to the second wavelength to form a white light;
a transparent housing covering the light emitting diode chips and the light mixing encapsulating layers; and
an ultraviolet protecting layer adhered to a surface of the transparent housing; when the ultraviolet protecting layer receives a light of ultraviolet band, color change occurs in the ultraviolet protecting layer to reflect or absorb the light of the ultraviolet band.

9. The light emitting diode package module of claim 8, wherein the ultraviolet protecting layer is a photochromic layer.

10. The light emitting diode package module of claim 9, wherein the ultraviolet protecting layer has a predetermined pattern to modulate the spatial distribution emitted by the light emitting diode chips when the color change occurs in the ultraviolet protecting layer.

11. The light emitting diode package module of claim 9, wherein the material of the photochromic layer is silver halide (AgX) or spiropyran.
